(19) United States
(12) Patent Application Publication
(10) Pub. No.: US 2026/0309802 A1
(43) Pub. Date: Oct. 8, 2026

(54) Battery Management Apparatus and Operating Method Thereof

(71) Applicant: LG Energy Solution, Ltd., Seoul (KR)

(72) Inventors: Yong Chul Sung, Daejeon (KR); Cheol Taek Kim, Daejeon (KR)

(73) Assignee: LG Energy Solution, Ltd., Seoul (KR)

(21) Appl. No.: 19/481,936

(22) PCT Filed: Jan. 25, 2024
(86) PCT No.: PCT/KR2024/001229

§ 371 Date: Nov. 6, 2025

(30) Foreign Application Priority Data
May 9, 2023 (KR) 10-2023-0060037

(51) Int. Cl. G01R 31/396; G01R 19/00; G01R 31/367; G01R 31/3835

(52) U.S. Cl. CPC G01R 31/396; G01R 19/003; G01R 31/367; G01R 31/3835

(57) ABSTRACT

Aspects of the disclosure are directed to diagnosing tab disconnection of a battery cell based on an open circuit voltage of the battery cell after charging or discharging, even when a voltage of the battery cell does not change suddenly. Diagnosing tab disconnection may include calculating a prediction value by applying the open circuit voltage of a battery cell to an average open circuit voltage of a plurality of battery cells, even when no sudden voltage behavior abnormality occurs, and diagnosing tab disconnection of the battery cell based on the prediction value and a measurement value. The prediction value may be calculated through linear regression, and diagnosing the battery cell may be based on a maximum deviation and a determination coefficient error rate between the prediction value and the measurement value.

### CROSS-REFERENCE TO RELATED APPLICATIONS

This application is a national phase entry under 35 U.S.C. § 371 of International Application No. PCT/KR2024/001229, filed on Jan. 25, 2024, which claims priority to Korean Patent Application No. 10-2023-0060037, filed on May 9, 2023, all of which is incorporated herein by reference.

### BACKGROUND

Secondary batteries are chargeable/dischargeable batteries and may include nickel (Ni)/cadmium (Cd) batteries, Ni/metal hydride (MH) batteries, and lithium-ion batteries. Among the secondary batteries, a lithium-ion battery has a higher energy density than the Ni/Cd batteries, Ni/MH batteries, etc. Moreover, the lithium-ion battery may be manufactured to be small and lightweight, such that the lithium-ion battery can be used as a power source of mobile devices. In addition, the lithium-ion battery is attracting attention as a next-generation energy storage medium for use as a power source of electric vehicles.

An abnormality of a battery cell may be diagnosed by diagnosing an abnormal behavior of a voltage of the battery cell based on a long-term/short-term moving average of voltages of battery cells. However, this approach uses a deviation from an average of battery cell voltages, where the abnormality of the battery cell may be diagnosed only when tab disconnection of the battery cell occurs or a sudden change in voltage occurs during reconnection of the disconnected battery cell. Moreover, this approach uses a real-time voltage, which increases system resources.

### BRIEF SUMMARY

Aspects of the disclosure are directed to diagnosing tab disconnection of a battery cell based on an open circuit voltage of the battery cell after charging or discharging, even when a voltage of the battery cell does not change suddenly. Diagnosing tab disconnection may include calculating a prediction value by applying the open circuit voltage of a battery cell to an average open circuit voltage of a plurality of battery cells, even when no sudden voltage behavior abnormality occurs, and diagnosing tab disconnection of the battery cell based on the prediction value and a measurement value. The prediction value may be calculated through linear regression, and diagnosing the battery cell may be based on a maximum deviation and a determination coefficient error rate between the prediction value and the measurement value.

Aspects of the disclosure provide for a battery management apparatus including: an information obtaining unit configured to obtain an open circuit voltage of each of a plurality of battery cells; and a controller configured to: calculate an average open circuit voltage for the open circuit voltage of each of the plurality of battery cells; calculate a first linear regression function related to an open circuit voltage of a first battery cell among the plurality of battery cells based on the open circuit voltage of the first battery cell and the average open circuit voltage; calculate a first error between a prediction value calculated based on the first linear regression function and the open circuit voltage of the first battery cell; and diagnose the first battery cell based on the first error.

In some examples, the information obtaining unit may be further configured to obtain the open circuit voltage of each of the plurality of battery cells for each charging after the plurality of battery cells are charged a plurality of times.

In some examples, the controller may be further configured to: calculate the average open circuit voltage for each charging based on an open circuit voltage of each of the plurality of battery cells obtained for each charging; and calculate the first linear regression function based on the average open circuit voltage calculated for each charging and the open circuit voltage of the first battery cell obtained for each charging.

In some examples, the controller may be further configured to: calculate a maximum deviation and a minimum deviation between the open circuit voltage of the first battery cell and the prediction value calculated based on the first linear regression function; calculate an error rate between the open circuit voltage of the first battery cell and the prediction value calculated based on the first linear regression function; and calculate a first error of the open circuit voltage of the first battery cell based on a difference between the maximum deviation and the minimum deviation and the error rate.

In some examples, the controller may be further configured to calculate the first error of the open circuit voltage of the first battery cell by multiplying the difference between the maximum deviation and the minimum deviation by the error rate.

In some examples, the error rate may be calculated based on a determination coefficient error rate.

In some examples, the controller may be further configured to diagnose that abnormality occurs in the first battery cell when the first error is greater than or equal to a preset value.

In some examples, the controller may be further configured to: calculate a linear regression function related to an open circuit voltage of each of the plurality of battery cells based on the open circuit voltage of each of the plurality of battery cells and the average open circuit voltage; calculate the error between the prediction value calculated based on the linear regression function and the open circuit voltage of each of the plurality of battery cells; and diagnose each of the plurality of battery cells based on the error.

In some examples, the information obtaining unit may be further configured to obtain the open circuit voltage of each of the plurality of battery cells by shifting for each reference a number of times.

In some examples, the information obtaining unit may be further configured to obtain the open circuit voltage of each of the plurality of battery cells for each discharging after the plurality of battery cells are discharged a plurality of times.

Aspects of the disclosure provide for an operating method of a battery management apparatus including: obtaining an open circuit voltage of each of a plurality of battery cells; calculating an average open circuit voltage for the open circuit voltage of each of the plurality of battery cells; calculating a first linear regression function related to an open circuit voltage of a first battery cell among the plurality of battery cells based on the open circuit voltage of the first battery cell and the average open circuit voltage; calculating a first error between a prediction value calculated based on the first linear regression function and the open circuit voltage of the first battery cell; and diagnosing the first battery cell based on the first error.

In some examples, the calculating of the first error between the prediction value calculated based on the first linear regression function and the open circuit voltage of the first battery cell may include: calculating a maximum deviation and a minimum deviation between the open circuit voltage of the first battery cell and the prediction value calculated based on the first linear regression function; calculating an error rate between the open circuit voltage of the first battery cell and the prediction value calculated based on the first linear regression function; and calculating a first error of the open circuit voltage of the first battery cell based on a difference between the maximum deviation and the minimum deviation and the error rate.

In some examples, the operating method may further include: calculating a linear regression function related to an open circuit voltage of each of the plurality of battery cells based on the open circuit voltage of each of the plurality of battery cells and the average open circuit voltage; calculating the error between the prediction value calculated based on the linear regression function and the open circuit voltage of each of the plurality of battery cells; and diagnosing each of the plurality of battery cells based on the error.

### BRIEF DESCRIPTION OF THE DRAWINGS

FIG. 1 is a block diagram of a battery pack according to aspects of the disclosure.

FIG. 2 is a block diagram of a battery management apparatus according to aspects of the disclosure.

FIG. 3 is a graph showing an example where a battery management apparatus calculates a linear regression function with respect to an open circuit voltage of each of a plurality of battery cells according to aspects of the disclosure.

FIG. 4 is a graph showing an example where a battery management apparatus calculates an error between a prediction value and a measurement value of each battery cell according to aspects of the disclosure.

FIG. 5 is a flowchart of an operating method of a battery management apparatus according to aspects of the disclosure.

FIG. 6 is a flowchart of further detail of the operating method of the battery management apparatus according to aspects of the disclosure.

FIG. 7 is a flowchart of further detail of the operating method of the battery management apparatus according to aspects of the disclosure.

FIG. 8 is a block diagram of a computing system for performing an operating method of a battery management apparatus according to aspects of the disclosure.

### DETAILED DESCRIPTION

The disclosure may be modified in various forms and have various examples, and specific examples thereof are shown by way of drawings and description below. It should be understood, however, that there is no intent to limit the disclosure to the specific examples, but on the contrary, the disclosure is to cover all modifications, equivalents, and alternatives falling within the spirit and technical scope of the disclosure. Like reference numerals refer to like elements throughout the description of the figures.

It will be understood that, although the terms such as first, second, A, B, and the like may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes combinations of a plurality of associated listed items or any of the plurality of associated listed items.

It will be understood that when an element is referred to as being “connected” to another element, it can be directly connected to the other element or an intervening element may be present.

The terms used herein are for the purpose of describing specific examples only and are not intended to limit the disclosure. As used herein, the singular forms “a”, “an” and “the” are intended to include the plural forms as well, unless the context clearly indicates otherwise. It will be further understood that the terms “comprises”, “comprising”, “includes”, “including” and/or “having”, when used herein, specify the presence of stated features, integers, steps, operations, constitutional elements, components and/or combinations thereof, but do not preclude the presence or addition of one or more other features, integers, steps, operations, constitutional elements, components, and/or combinations thereof.

Aspects of the disclosure may be provided in a computer program product. The computer program product may be traded as a product between a seller and a buyer. The computer program product may be distributed in the form of a machine-readable storage medium, e.g., compact disc read only memory (CD-ROM)), or be distributed, e.g., downloaded or uploaded, online via an application store, or be distributed between two user devices directly. If distributed online, at least part of the computer program product may be temporarily generated or at least temporarily stored in the machine-readable storage medium, such as memory of the manufacturer's server, a server of the application store, or a relay server.

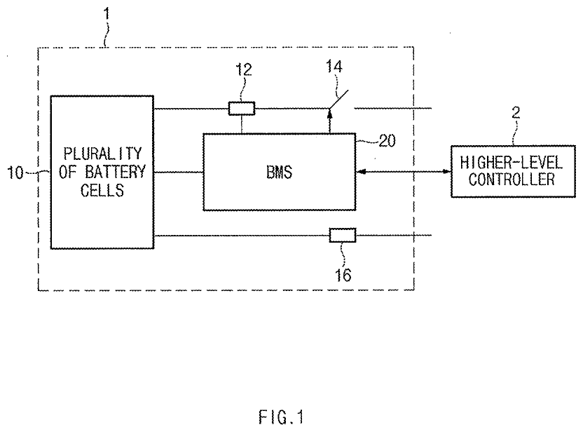

FIG. 1 is a block diagram showing a configuration of a battery pack 1 and a higher-level controller 2 according to aspects of the disclosure. The battery pack 1 may include a plurality of battery cells 10, a sensor 12, a switching unit 14, and a battery management system 20.

The plurality of battery cells 10 may include one or more chargeable/dischargeable battery cells. The switching unit 14 may be serially connected to positive (+) terminal sides or negative (−) terminal sides of the plurality of battery cells 10 to control a charging/discharging current flow of the plurality of battery cells 10. For example, the switching unit 14 may be at least one relay and/or magnetic contactor to be used according to specifications of the battery pack 1.

The battery management system 20 may control and manage the plurality of battery cells 10 to prevent over-charging and over-discharging by monitoring parameter values of the battery pack 1, e.g., voltage, current, and/or temperature, from the sensor 12. The battery management system 20 may be an interface for receiving measurement values of the parameter values, which may include a plurality of terminals and a circuit connected thereto to process input values. The battery management system 20 may control the switching unit 14 to be on or off, and may be connected to the plurality of battery cells 10 to monitor the state of each battery cell 10.

The higher-level controller 2 may transmit a control signal regarding the plurality of battery cells 10 to the battery management system 20. Thus, the battery management system 20 may also be controlled based on a signal applied from the higher-level controller 2.

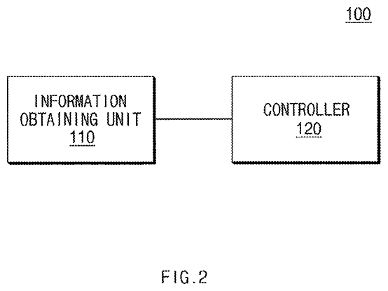

FIG. 2 is a block diagram of a battery management apparatus 100 according to aspects of the disclosure. The battery management apparatus 100 may be included as part of a battery management system 20, such as the battery management system 20 as depicted in FIG. 1. Alternatively, or additionally, the battery management apparatus 100 may be separate from the battery management system and may be included as part of the battery pack or a device separate from the battery pack, e.g., a server, a cloud, a charger, and/or a charger/discharger.

The battery management apparatus 100 may include an information obtaining unit 110 and a controller 120. The information obtaining unit 110 may obtain an open circuit voltage of each of a plurality of battery cells. For example, the information obtaining unit 110 may obtain an open circuit voltage after each of the plurality of battery cells is charged and/or discharged. As another example, the information obtaining unit 110 may obtain the open circuit voltage of each of the plurality of battery cells for each charging and/or discharging after the plurality of battery cells are charged and/or discharged a plurality of times.

The information obtaining unit 110 may obtain the open circuit voltage of each of the plurality of battery cells by performing shifting based on a reference number of times the open circuit voltage is obtained. For example, when the reference number of times is 10, the information obtaining unit 110 may delete an open circuit voltage of each of a plurality of battery cells from a 1^{st} round upon obtaining the open circuit voltage of each of the plurality of battery cells in the 11^{th} round. In this example, the controller 120 may calculate a linear regression function of each of the plurality of battery cells based on the open circuit voltage of each of the plurality of battery cells for the reference number of times to diagnose each of the plurality of battery cells.

The controller 120 may calculate an average open circuit voltage for the open circuit voltage of each of the plurality of battery cells. For example, the controller 120 may calculate an average open circuit voltage for the open circuit voltage of each of the plurality of battery cells after each of the plurality of battery cells is charged and/or discharged. As another example, the controller 120 may calculate an average open circuit voltage for the open circuit voltage of each of the plurality of battery cells a plurality of times after each charging or discharging is performed when charging and/or discharging is performed the plurality of times.

The controller 120 may calculate a linear regression function related to an open circuit voltage of each of the plurality of battery cells, based on the open circuit voltage of each of the plurality of battery cells and the average open circuit voltage. For example, the controller 120 may calculate a first linear regression function related to an open circuit voltage of a first battery cell among the plurality of battery cells. The first battery cell may be any one of the plurality of battery cells. The controller 120 may calculate the first linear regression function based on the average open circuit voltage calculated for each charging and the open circuit voltage of the first battery cell, obtained for each charging.

For example, the controller 120 may calculate the first linear regression function by using Equation (1):

$$y = ax + b \qquad ( 1 )$$

where x is the average open circuit voltage of the plurality of battery cells and y is a prediction value for the open circuit voltage of the first battery cell. The controller 120 may calculate a and b to reduce, e.g., minimize, an error between a prediction value and a measurement value for the open circuit voltage of the first battery cell. The error between the prediction value and the measurement value for the open circuit voltage of the first battery cell may include at least one of an absolute error, a relative error, a percentage error, a root mean square error, and/or a determination coefficient error, as examples. The controller 120 may calculate the linear regression function for each of the plurality of battery cells by using Equation 1.

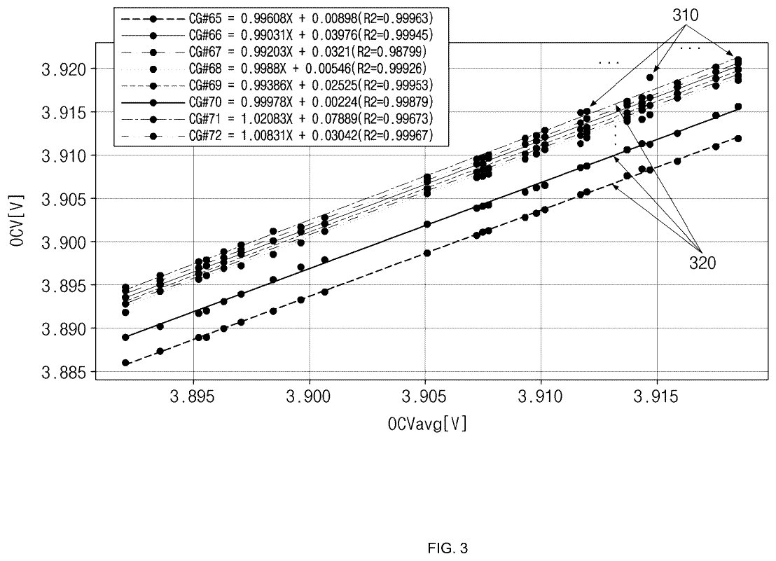

FIG. 3 shows an example where the battery management apparatus 100 calculates a linear regression function with respect to an open circuit voltage of each of a plurality of battery cells. The controller 120 may calculate a linear regression function 320 of each of the plurality of battery cells based on a measurement value 310 of the open circuit voltage of each of the plurality of battery cells and an average open circuit voltage of the plurality of battery cells. For example, the controller 120 may calculate the linear regression function 320 by applying the measurement value 310 of the open circuit voltage of each of the plurality of battery cells to the average open circuit voltage of the plurality of battery cells. The controller 120 may calculate a prediction value for the open circuit voltage of each of the plurality of battery cells based on the linear regression function of each of the plurality of battery cells. The prediction value may correspond to the average open circuit voltage.

The controller 120 may calculate an error rate between the measurement value and the prediction value based on the linear regression function of each of the plurality of battery cells for each of the plurality of battery cells, such as based on a determination coefficient error rate. For example, the controller 120 may calculate the error rate for each of the plurality of battery cells by subtracting the determination coefficient error rate from 1. In this example, the determination coefficient error rate has a value closer to 1 for a smaller error, where a smaller calculated error rate may correspond to a smaller error between the measurement value and the prediction value, and a larger calculated error rate may mean a larger error between the measurement value and the prediction value.

Referring back to FIG. 2, the controller 120 may calculate a first error between the prediction value calculated based on the first linear regression function and the open circuit voltage of the first battery cell. For example, the controller 120 may calculate a maximum deviation and a minimum deviation between the open circuit voltage of the first battery cell and the prediction value calculated based on the first linear regression function, calculate an error rate between the open circuit voltage of the first battery cell and the prediction value calculated based on the first linear regression function, and calculate the first error for the open circuit voltage of the first battery cell based on a difference and an error rate between the maximum deviation and the minimum deviation. For example, the controller 120 may calculate the first error of the open circuit voltage of the first battery cell by multiplying the difference between the maximum deviation and the minimum deviation by the error rate. The error rate may be calculated based on the determination coefficient error rate. For example, the error rate may be a value obtained by subtracting the determination coefficient error rate from 1.

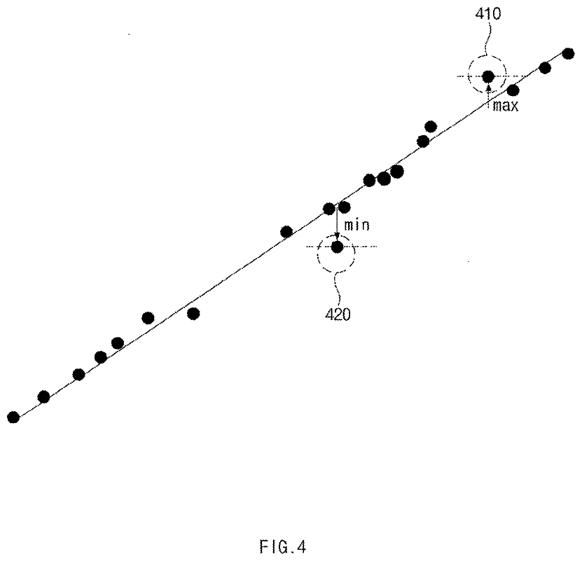

FIG. 4 shows an example where the battery management apparatus 100 calculates an error between a prediction value and a measurement value of each battery cell. The controller 120 may compare the measurement value of the open circuit voltage of the first battery cell with the first linear regression function to calculate a deviation. For example, the controller 120 may calculate an open circuit voltage measurement value 410 having a maximum deviation from the first linear regression function and an open circuit voltage measurement value 420 having a minimum deviation from the first linear regression function, among open circuit voltage measurement values of the first battery cell. In this example, the controller 120 may calculate a deviation between the open circuit voltage measurement value 410 having the maximum deviation and the first linear regression function and calculate a deviation between the open circuit voltage measurement value 420 having the minimum deviation and the first linear regression function to calculate a difference between the maximum deviation and the minimum deviation. While FIG. 4 shows a measurement value of an open circuit voltage and a linear regression function being compared for one battery cell, the controller 120 may compare an open circuit voltage of each of a plurality of battery cells with a linear regression function of each of the plurality of battery cells to calculate a maximum deviation and a minimum deviation for each of the plurality of battery cells.

Referring back to FIG. 2, the controller 120 may diagnose the first battery cell based on the first error. For example, the controller 120 may diagnose that an abnormality occurs in the first battery cell when the first error is greater than or equal to a preset value. For example, the controller may diagnose whether a tab of the first battery cell is disconnected based on the first error.

For example, when the first error is calculated by multiplying the difference between the maximum deviation and the minimum deviation of the first battery cell by the error rate, the controller 120 may diagnose whether an abnormality occurs in the first battery cell by considering the maximum deviation, the minimum deviation, and the error rate at the same time.

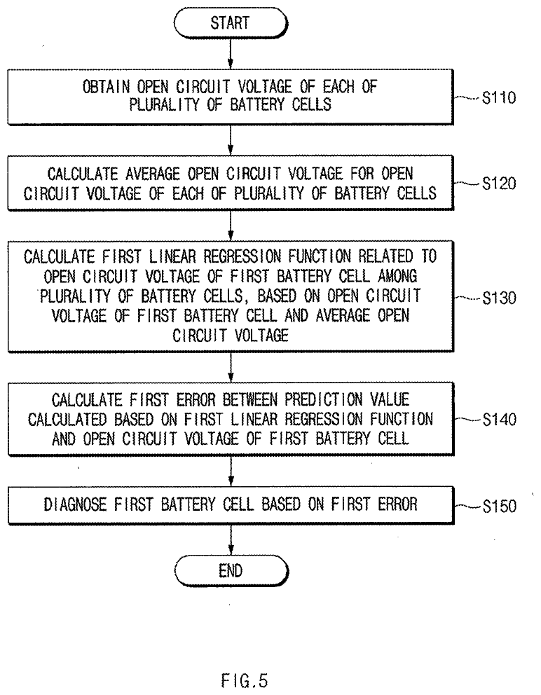

FIG. 5 is a flowchart of an operating method of a battery management apparatus according to aspects of the disclosure. The operations shown in FIG. 5 may be performed by a battery management apparatus, such as the battery management apparatus 100 of FIG. 2.

In operation S110, the information obtaining unit 110 obtains the open circuit voltage of each of the plurality of battery cells.

In operation S120, the controller 120 calculates an average open circuit voltage for the open circuit voltages of each of the plurality of battery cells. In operation S130, the controller 120 calculates a first linear regression function related to an open circuit voltage of a first battery cell among the plurality of battery cells based on the open circuit voltage of the first battery cell and the average open circuit voltage.

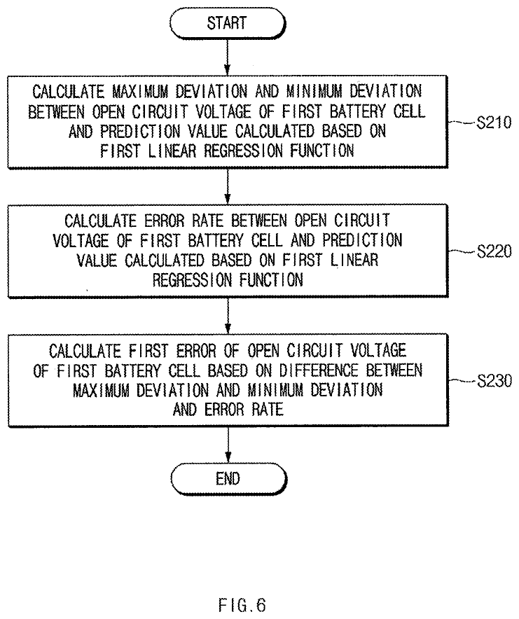

In operation S140, the controller 120 calculates a first error between the prediction value calculated based on the first linear regression function and the open circuit voltage of the first battery cell. FIG. 6 is a flowchart of further detail of the operating method of the battery management apparatus 100 according to aspects of the disclosure. In operation S210, the controller 120 may calculate the maximum deviation and the minimum deviation between the open circuit voltage of the first battery cell and the prediction value calculated based on the first linear regression function. In operation S220, the controller 120 may calculate the error rate between the open circuit voltage of the first battery cell and the prediction value calculated based on the first linear regression function. In operation S230, the controller 120 may calculate the first error of the open circuit voltage of the first battery cell based on the difference between the maximum deviation and the minimum deviation and the error rate.

Referring back to FIG. 5, in operation S150, the controller 120 diagnoses the first battery cell based on the first error.

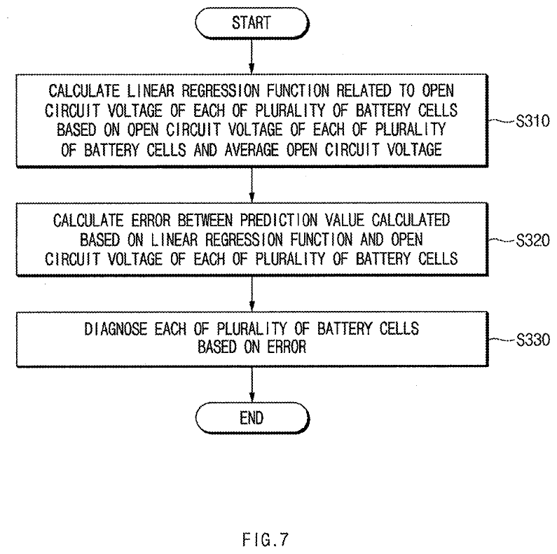

FIG. 7 is a flowchart of further detail of the operating method of the battery management apparatus 100 according to aspects of the disclosure. In operation S310, the controller 120 may calculate the linear regression function related to an open circuit voltage of each of the plurality of battery cells based on the open circuit voltage of each of the plurality of battery cells and the average open circuit voltage. In operation S320, the controller 120 may calculate the error between the prediction value calculated based on the linear regression function and the open circuit voltage of each of the plurality of battery cells. In operation S330, the controller 120 may diagnose each of the plurality of battery cells based on the error.

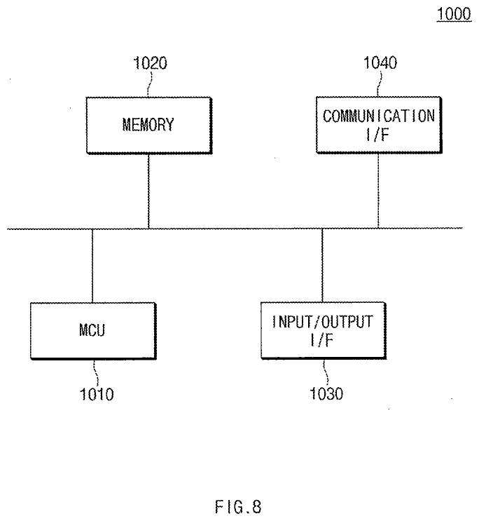

FIG. 8 is a block diagram showing a hardware configuration of a computing system 1000 for performing an operating method of a battery management apparatus according to aspects of the disclosure. The computing system 1000 may include an MCU 1010, a memory 1020, an input/output I/F 1030, and a communication I/F 1040.

The MCU 1010 may be a processor that executes various programs, e.g., a battery cell open circuit voltage collection program, a linear regression function calculation program, and/or an error calculation program, stored in the memory 1020, processes various data including an open circuit voltage of a battery cell, a linear regression function, and/or an error through these programs, and performs the above-described functions of the controller 120 included in the battery management apparatus 100 shown in FIG. 2.

The memory 1020 may store various programs such as a battery cell open circuit voltage collection program, a linear regression function calculation program, an error calculation program, and/or a battery cell diagnosis program. Moreover, the memory 1020 may store various information such as an open circuit voltage of a battery cell, a linear regression function, and/or an error.

The memory 1020 may be one or more memories. The memory 1020 may be volatile memory or non-volatile memory. For the memory 1020 as the volatile memory, random access memory (RAM), dynamic RAM (DRAM), static RAM (SRAM), etc., may be used, as examples. For the memory 1020 as the nonvolatile memory, read only memory (ROM), programmable ROM (PROM), electrically alterable ROM (EAROM), erasable PROM (EPROM), electrically erasable PROM (EEPROM), flash memory, etc., may be used, as examples. The memory 1020 may be a transitory or non-transitory computer readable medium. As such, a computer program according to aspects of the disclosure may be recorded in the memory 1020 and processed by the MCU 1010, thus being implemented as a module that performs operations shown in FIGS. 5-7.

The input/output I/F 1030 may provide an interface for transmitting and receiving data by connecting an input device (not shown) such as a keyboard, a mouse, and/or a touch panel, and an output device (not shown), such as a display, to the MCU 1010.

The communication I/F 1040 may be configured to transmit and receive various data to and from a server and may be capable of supporting wired or wireless communication. For example, the battery management apparatus may transmit and receive various information including the open circuit voltage of the battery cell, the linear regression function, and/or the error, from an external server separately provided through the communication I/F 1040.

Unless otherwise stated, the foregoing alternative examples are not mutually exclusive but may be implemented in various combinations to achieve unique advantages. As these and other variations and combinations of the features discussed above can be utilized without departing from the subject matter defined by the claims, the foregoing description of the examples should be taken by way of illustration rather than by way of limitation of the subject matter defined by the claims. In addition, the provision of the examples described herein, as well as clauses phrased as “such as,” “including” and the like, should not be interpreted as limiting the subject matter of the claims to the specific examples; rather, the examples are intended to illustrate only one of many possible implementations. Further, the same reference numbers in different drawings can identify the same or similar elements.

1.-13. (canceled)

14. A battery management apparatus comprising one or more processors configured to:
obtain an open circuit voltage of each of a plurality of battery cells;
calculate an average open circuit voltage for the open circuit voltage of each of the plurality of battery cells;
calculate a first linear regression function related to an open circuit voltage of a first battery cell among the plurality of battery cells based on the open circuit voltage of the first battery cell and the average open circuit voltage;
calculate a first error between a prediction value calculated based on the first linear regression function and the open circuit voltage of the first battery cell; and
diagnose the first battery cell based on the first error.

15. The battery management apparatus of claim 14, wherein the one or more processors are further configured to obtain the open circuit voltage of each of the plurality of battery cells for each charging after the plurality of battery cells are charged a plurality of times.

16. The battery management apparatus of claim 15, wherein the one or more processors are further configured to:
calculate the average open circuit voltage for each charging based on an open circuit voltage of each of the plurality of battery cells obtained for each charging; and
calculate the first linear regression function based on the average open circuit voltage calculated for each charging and the open circuit voltage of the first battery cell obtained for each charging.

17. The battery management apparatus of claim 14, wherein the one or more processors are further configured to:
calculate a maximum deviation and a minimum deviation between the open circuit voltage of the first battery cell and the prediction value calculated based on the first linear regression function;
calculate an error rate between the open circuit voltage of the first battery cell and the prediction value calculated based on the first linear regression function; and
calculate a first error of the open circuit voltage of the first battery cell based on a difference between the maximum deviation and the minimum deviation and the error rate.

18. The battery management apparatus of claim 17, wherein the one or more processors are further configured to calculate the first error of the open circuit voltage of the first battery cell by multiplying the difference between the maximum deviation and the minimum deviation by the error rate.

19. The battery management apparatus of claim 17, wherein the error rate is calculated based on a determination coefficient error rate.

20. The battery management apparatus of claim 14, wherein the one or more processors are further configured to diagnose that abnormality occurs in the first battery cell when the first error is greater than or equal to a preset value.

21. The battery management apparatus of claim 14, wherein the one or more processors are further configured to:
calculate a linear regression function related to an open circuit voltage of each of the plurality of battery cells based on the open circuit voltage of each of the plurality of battery cells and the average open circuit voltage;
calculate the error between the prediction value calculated based on the linear regression function and the open circuit voltage of each of the plurality of battery cells; and
diagnose each of the plurality of battery cells based on the error.

22. The battery management apparatus of claim 14, wherein the one or more processors are further configured to obtain the open circuit voltage of each of the plurality of battery cells by shifting for each reference number of times.

23. The battery management apparatus of claim 14, wherein the one or more processors are further configured to obtain the open circuit voltage of each of the plurality of battery cells for each discharging after the plurality of battery cells are discharged a plurality of times.

24. An operating method of a battery management apparatus comprising:
obtaining an open circuit voltage of each of a plurality of battery cells;
calculating an average open circuit voltage for the open circuit voltage of each of the plurality of battery cells;
calculating a first linear regression function related to an open circuit voltage of a first battery cell among the plurality of battery cells based on the open circuit voltage of the first battery cell and the average open circuit voltage;
calculating a first error between a prediction value calculated based on the first linear regression function and the open circuit voltage of the first battery cell; and
diagnosing the first battery cell based on the first error.

25. The operating method of claim 24, further comprising obtaining the open circuit voltage of each of the plurality of battery cells for each charging after the plurality of battery cells are charged a plurality of times.

26. The operating method of claim 25, further comprising:
calculating the average open circuit voltage for each charging based on an open circuit voltage of each of the plurality of battery cells obtained for each charging; and
calculating the first linear regression function based on the average open circuit voltage calculated for each charging and the open circuit voltage of the first battery cell obtained for each charging.

27. The operating method of claim 24, wherein the calculating of the first error between the prediction value calculated based on the first linear regression function and the open circuit voltage of the first battery cell comprises:
calculating a maximum deviation and a minimum deviation between the open circuit voltage of the first battery cell and the prediction value calculated based on the first linear regression function;
calculating an error rate between the open circuit voltage of the first battery cell and the prediction value calculated based on the first linear regression function; and
calculating a first error of the open circuit voltage of the first battery cell based on a difference between the maximum deviation and the minimum deviation and the error rate.

28. The operating method of claim 27, further comprising calculating the first error of the open circuit voltage of the first battery cell by multiplying the difference between the maximum deviation and the minimum deviation by the error rate.

29. The operating method of claim 27, wherein the error rate is calculated based on a determination coefficient error rate.

30. The operating method of claim 24, further comprising diagnosing that abnormality occurs in the first battery cell when the first error is greater than or equal to a preset value.

31. The operating method of claim 24, further comprising:
calculating a linear regression function related to an open circuit voltage of each of the plurality of battery cells based on the open circuit voltage of each of the plurality of battery cells and the average open circuit voltage;
calculating the error between the prediction value calculated based on the linear regression function and the open circuit voltage of each of the plurality of battery cells; and
diagnosing each of the plurality of battery cells based on the error.

32. The operating method of claim 24, further comprising obtaining the open circuit voltage of each of the plurality of battery cells by shifting for each reference number of times.

33. A non-transitory computer readable medium for storing instructions that, when executed by one or more processors, cause the one or more processors to perform an operating method of a battery management apparatus, the operating method comprising:
obtaining an open circuit voltage of each of a plurality of battery cells;
calculating an average open circuit voltage for the open circuit voltage of each of the plurality of battery cells;
calculating a first linear regression function related to an open circuit voltage of a first battery cell among the plurality of battery cells based on the open circuit voltage of the first battery cell and the average open circuit voltage;
calculating a first error between a prediction value calculated based on the first linear regression function and the open circuit voltage of the first battery cell; and
diagnosing the first battery cell based on the first error.
